(19) United States
(12) Patent Application Publication
(10) Pub. No.: US 2010/0110659 A1
(43) Pub. Date: May 6, 2010

(54) LED LIGHTING UNIT AND METHOD FOR MANUFACTURING THE SAME

(76) Inventor: Toshiyuki Nakajima, Tokyo (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/609,178

(22) Filed: Oct. 30, 2009

(30) Foreign Application Priority Data
Oct. 30, 2008 (JP) 2008-279991

(51) Int. Cl. F21V 9/16; H01L 33/00; H01L 21/00

(52) U.S. Cl. 362/84; 257/88; 438/26; 257/100; 257/E33.067; 257/E21.001

(57) ABSTRACT

An LED lighting unit and a method for manufacturing the same can include a first cavity and a second cavity which has a depth that is different from that of the first cavity. The first and the second cavities can include an LED chip and an encapsulating resin including a phosphor. Color temperatures of light emitted from these cavities can be controlled by changing thicknesses of the encapsulating resin based on the depth of each of these cavities so as to be located on a substantially black body, and the variability of the optical characteristics can be reduced due to the simple structure. Thus, the LED lighting unit can emit light having a favorable color temperature that is close to a natural light using light that is emitted from these cavities. The manufacturing method can include forming the thickness of the encapsulating resin with accuracy, and therefore can provide a suitable LED lighting unit for various lighting systems.

This application claims the priority benefit under 35 U.S.C. §119 of Japanese Patent Application No. 2008-279991 filed on Oct. 30, 2008, which is hereby incorporated in its entirety by reference.

### BACKGROUND

1. Field

The presently disclosed subject matter relates to LED lighting units and to a manufacturing method for these LED lighting units, and more particularly to the LED lighting units having a favorable color temperature in which a plurality of light-emitting portions includes the respective LED chips and a phosphor, and to the manufacturing method for these lighting units.

2. Description of the Related Art

Lighting units having various color temperatures have been commercialized in order to meet customer's needs such as matching an illuminating light to interior decorating and atmosphere in a room. The color temperatures include a wide range from a white light of cool color such as a natural light in daytime to a warm color such as light from a light bulb. To that end, LED lighting units having a variable color temperature in which LED chips are used as a light source have been developed.

For example, an LED lighting unit having a variable color temperature is disclosed in Patent Document No. 1 (Japanese Patent Application Laid Open JP2005-101296). FIG. 8 is a top view showing a conventional LED lighting unit having a variable color temperature, which is disclosed in Patent Document No. 1. The conventional LED lighting unit includes: a casing 50 that includes a concave portion 51 on a base board; a die bonding pad 52 that is exposed on a bottom surface of the concave portion 51; and two blue LED chips 53a and 53b (hereafter referred to as the LED chips) that are mounted on the die bonding pad 52 at a predetermined interval, wherein each bottom electrode of the LED chips 53a and 53b are electrically connected to the die bonding pad 52 as shown in FIG. 8.

The concave portion 51 in the casing 50 also includes two wire bonding pads 54a and 54b on the bottom surface thereof which project, and each top electrode of the LED chips 53a and 53b is electrically connected to each of the wire bonding pads 54a and 54b via bonding wires 55a and 55b. In addition, the die bonding pad 52 to which the LED chips 53a and 53b is mounted thereon is connected to a common terminal 56 that is located on a bottom surface of the casing 50 while passing through the base board. Each of the wire bonding pads 54a and 54b that is connected to each top electrode of the LED chips 53a and 53b via each of bonding wires 55a and 55b is connected to each of terminals 57a and 57b, which are located on the bottom surface of the casing 50 while passing through the base board.

The LED lighting unit also includes two elliptical cylinders 58a and 58b that are located so as to integrally cover each of the LED chips 53a, 53b and each of the bonding wires 55a and 55b connected to the LED chips 53a and 53b. A first resin layer 59a that is made by dispersing a yellow phosphor into an epoxy resin is disposed in the one elliptical cylinder 58a. A second resin layer 59b that is made by dispersing yellow phosphor and an orange phosphor into the epoxy resin is disposed in the other elliptical cylinder 58b. In addition, a third resin layer 60 is located overall in the concave portion 51 so as to cover the first resin layer 59a and the second resin layer 59b therewith.

When the LED chips 53a and 53b are turned on by providing a power supply between the common terminal 56 and the terminal 57a and between the common terminal 56 and the terminal 57b, white light can be emitted from a first light-emitting portion 61a and a second light-emitting portion 61b. In this case, the white light that is emitted from the first light-emitting portion 61a has a certain color temperature, for instance, between 6000K and 7000K. The white light that is emitted from the second light-emitting portion 61b has another color temperature, for example, between 3000K and 4000K.

Therefore, a difference between the color temperatures of the white lights becomes 2,000K or more. When the LED chips 53a and 53b are driven by a direct current, the brightness of the white light emitted from each of the first light-emitting portion 61a and the second light-emitting portion 61b can be controlled by changing a current value of the direct current. When the LED chips 53a and 53b are driven by a pulse or alternating current, the brightness of the white light emitted from each of the first light-emitting portion 61a and the second light-emitting portion 61b can be controlled by changing a duty ratio of the pulse or alternating current.

Thus, the conventional LED lighting unit can emit a mixture light having a color temperature that can be charted on an approximate line between the respective white chromaticity of the light emitted from each of the first light-emitting portion 61a and the second light-emitting portion 61b which are located close to the black body in a CIE chromaticity diagram by using the above-described current controller for the LED chips 53a and 53b.

The above-referenced Patent Document is listed below, and is hereby incorporated with its English abstract and translation in its entirety.

1. Patent document No. 1: Japanese Patent Application Laid Open JP2005-101296

However, in the above-described conventional LED lighting unit, the phosphor that is included in the first resin layer 59a disposed in the first light-emitting portion 61a and the phosphor that is included in the second resin layer 59b disposed in the second light-emitting portion 61b are different phosphors with respect to each other. Two mixing processes of the epoxy resin and these different phosphors are typically carried out under strict density management. However, it may be difficult to avoid causing respective variability in distributing densities between the epoxy resin and these different phosphors even when trying to control the respective accuracy of the different distributing densities within ranges of two predetermined accuracies in the mixing processes.

Thus, in the first resin layer 59a and the second resin layer 59b, an individual variability of the distributing densities between the epoxy resin and these phosphors may be caused. The individual variability of these distributing densities may then cause respective variability in the optical characteristics such as brightness and wavelength distributions of the light emitted from the first light-emitting portion 61a and the second light-emitting portion 61b.

Therefore, because the mixture light emitted from the LED lighting unit consists of the respective lights emitted from the first light-emitting portion 61a and the second light-emitting portion 61b, the LED lighting unit may emit mixture light including respective variability in the optical characteristics such as brightness and wavelength distributions of the light emitted from the first light-emitting portion 61a and the second light-emitting portion 61b.

As the result, it may be difficult for the LED lighting unit to reliably emit light having a favorable color temperature because the color reproducibility with regard to the optical characteristics may be difficult to control even if the color temperature is controlled by the current control or the duty-ratio control.

The disclosed subject matter has been devised to consider the above and other problems, features and characteristics. Thus, an embodiment of the disclosed subject matter can include an LED lighting unit having a plurality of light-emitting portions that can emit a mixture light having a favorable color temperature and high color reproducibility with stability between two color temperatures by using mixture lights having different color temperatures emitted from the light-emitting portions. The lighting unit can be configured with one kind of LED chip and one kind of encapsulating resin including a phosphor.

### SUMMARY

The presently disclosed subject matter has been devised in view of the above and other problems, features, and characteristics. Another aspect of the disclosed subject matter includes methods of manufacture that provide various LED lighting units having a favorable color temperature such that color temperature is close to a natural color using a simple manufacturing machine and which can be used even in a small lot production system.

According to an aspect of the disclosed subject matter, an LED lighting unit can include: a casing having a first surface and a first cavity and a second cavity composed of a laminate board, the laminate board including a plurality of laminated insulating boards each having substantially respective uniform or equal thickness, the first cavity including an opening toward the first surface and a bottom surface that is formed by exposing an insulating board of the laminate board, the second cavity including an opening toward the first surface and a bottom surface that is formed by exposing an insulating board of the laminate board, and the second cavity located adjacent the first cavity; a plurality of a pair of die bonding pads and wire bonding pads adjacently located on both bottom surfaces of the first cavity and the second cavity; and a plurality of LED chips having electrodes and a peak wavelength mounted on the die bonding pads, and each of the electrodes thereof electrically connected to each of the die bonding pads and the wire bonding pads.

The LED lighting unit can also include an encapsulating resin having a first surface and a second surface composed of a transparent resin and a phosphor, disposed at least in the first cavity and the second cavity so as to encapsulate the LED chips therewith, the first surface thereof being substantially parallel to the bottom surface of the first cavity, the second surface thereof being substantially parallel to the bottom surface of the second cavity, and wherein a distance between the first surface and the bottom surface of the first cavity is configured to become shorter than a distance between the second surface and the bottom surface of the second cavity.

In the above-described exemplary LED lighting unit, the casing can be composed of a first insulating board including a pair of die bonding pads and wire bonding pads and electrodes for receiving a power supply, a second insulating board including a pair of die bonding pads and wire bonding pads and a through-bore, and a third insulating board including a first through-bore and a second through-bore so that the bonding pads and the wire bonding pads of the first and the second insulating board can be respectively exposed in the first and the second through-bore of the third insulating board by connecting the second through-bore to the through-bore of the second insulating board.

In the above-described exemplary LED lighting units, each inner surface of the first cavity and the second cavity can be formed as a continuous and smooth surface, and both openings of the first cavity and the second cavity can be configured in a substantially same shape. The first and the second surface of the encapsulating resin can be the substantially same level as the first surface of the casing. In addition, the peak wavelength of the LED chips can be within the range of a wavelength of blue light or ultraviolet light, and each chromaticity of light emitted from the first cavity and the second cavity can be located on a substantially black body or at white area that is close to the black body in CIE chromaticity diagram.

According to the exemplary LED lighting unit, the plurality of light-emitting portions that includes the first and the second cavity can be configured to include one kind of LED chip and one kind of encapsulating resin including a phosphor in the cavities. The optical characteristics of light emitted from the light-emitting portions can be controlled by changing thicknesses of the encapsulating resin based upon depths of the cavities. Thus, variability of optical characteristics such as the brightness, the wavelength distribution and the like can be reduced due to the simple structure, and therefore the LED lighting unit can emit light having a favorable color temperature while maintaining high color reproducibility.

In addition, light emitted from the first cavity and the second cavity can be close to natural light because the chromaticity can be located on the substantially black body in CIE chromaticity diagram with confidence. Therefore, because the LED lighting unit can also emit a mixture light having a favorable color temperature located between the color temperature of the light emitted from the first and the second cavity by controlling driving currents for the LED chips, the disclosed subject matter can provide LED lighting units suitable for various lighting systems.

Another aspect of the disclosed subject matter includes a method for manufacturing an LED lighting unit (for example, the above-described LED lighting unit) that can include: providing a casing that includes a first surface, a first cavity having a bottom surface substantially parallel to the first surface, and a second cavity having a bottom surface substantially parallel to the first surface; mounting a plurality of LED chips on the bottom surface in each of the first cavity and the second cavity; encapsulating the LED chips in the first cavity and the second cavity with an encapsulating resin; solidifying the encapsulating resin; and cutting off the encapsulating resin such that the resin is at substantially the same level as the first surface of the casing in the solidifying process or after the solidifying process.

In the above-described manufacturing method for the LED lighting unit, the method can further include: placing a mask plate having a first surface that includes a hole or holes corresponding to at least one of the first cavity and the second cavity and which are formed in a substantially uniform thickness on the first surface of the casing so as to be located opposite the first surface before the encapsulating process; and cutting off the encapsulating resin so as to become the substantially same level as the first surface of the mask plate in the cutting process. In this case, a distance between the first surface of the casing or the mask plate and the bottom surface of the first cavity is configured to become shorter than a distance between the first surface of the casing or the mask plate and the bottom surface of the second cavity.

According to the above-described method for manufacturing the LED lighting unit, the thicknesses of the encapsulating resins based upon the depths of the cavities can be formed with high accuracy using a simple manufacturing machine. In this case, the thicknesses of the encapsulating resins can also be adjusted individually using the mask plate. Thus, the manufacturing method can provide the various LED lighting units that can emit suitable lights having favorable color temperatures with stability for the lighting systems.

### BRIEF DESCRIPTION OF THE DRAWINGS

The above and other characteristics and features of the disclosed subject matter will become clear from the following description with reference to the accompanying drawings, wherein:

FIG. 1 is a top view showing an exemplary embodiment of an LED lighting unit made in accordance with principles of the disclosed subject matter;

FIG. 2 is a cross-section view taken along line A-A shown in FIG. 1 showing the LED lighting unit of FIG. 1;

FIG. 3 is a cross-section view taken along line B-B shown in FIG. 1 showing the LED lighting unit of FIG. 1;

FIG. 4a is a side cross-section view showing a process in an exemplary manufacturing method for an LED lighting unit made in accordance with principles of the disclosed subject matter, and FIGS. 4b and 4c are side cross-section views showing variations in the process;

FIG. 5 is a side cross-section view for explaining an optical structure in the exemplary embodiment of the LED lighting unit made in accordance with principles of the disclosed subject matter;

FIG. 6 is a chromaticity diagram showing a chromaticity on a chromaticity coordinate in the exemplary embodiment of the LED lighting unit made in accordance with principles of the disclosed subject matter;

FIG. 7 is a graph showing the relation between color temperature and depth of concave portion in an evaluation result of test samples made in accordance with principles of the disclosed subject matter; and

FIG. 8 is a top view showing a conventional LED lighting unit having a variable color temperature.

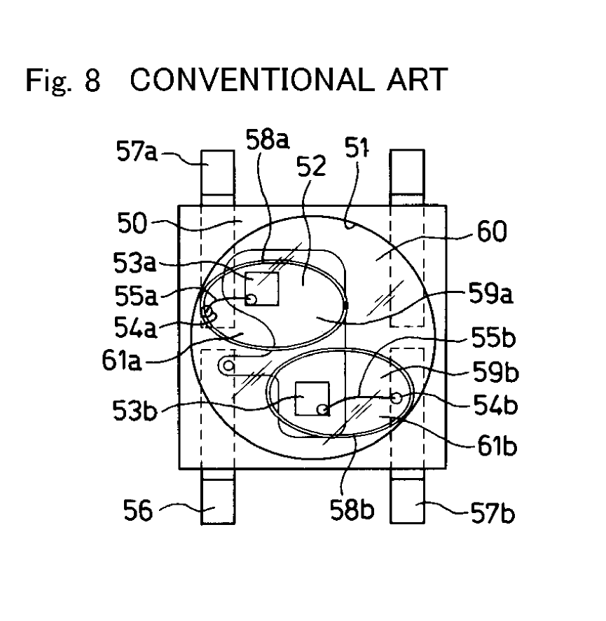

### DETAILED DESCRIPTION OF EXEMPLARY EMBODIMENTS

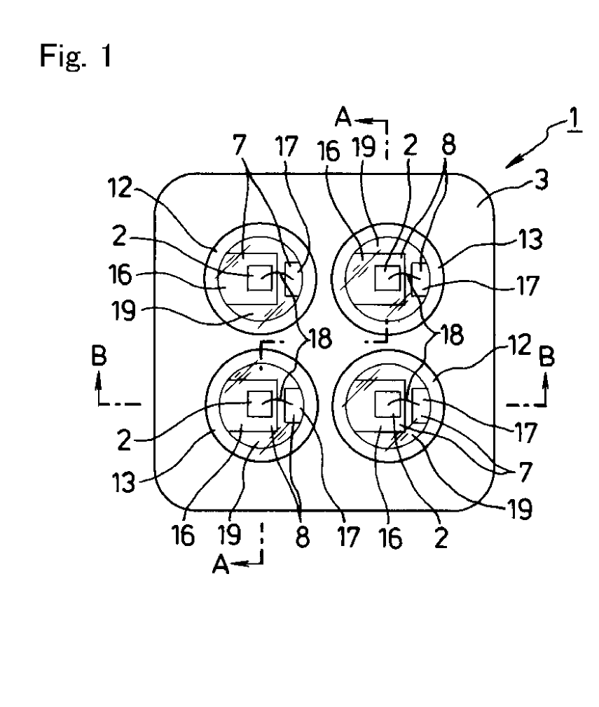

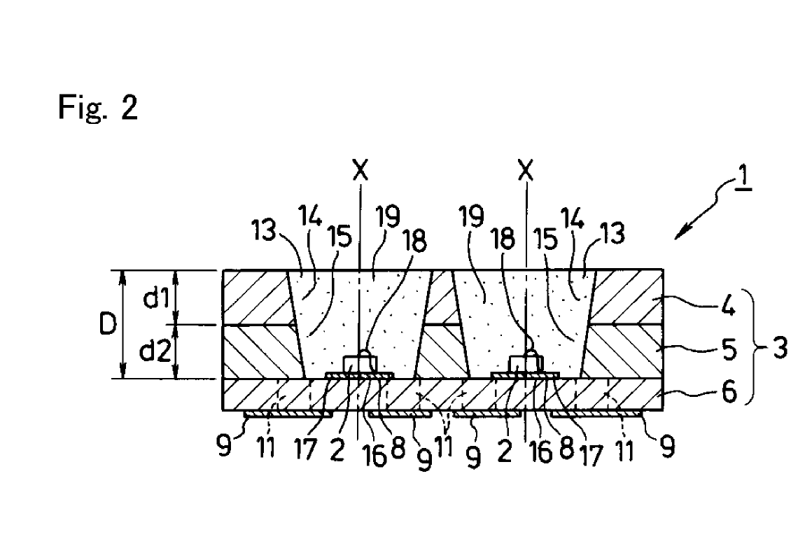

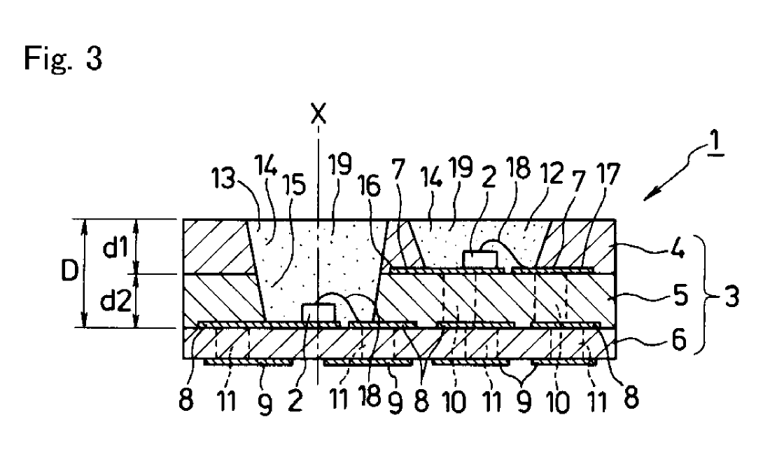

The disclosed subject matter will now be described in detail with reference to FIGS. 1 to 7. FIG. 1 is a top view showing an exemplary embodiment of an LED lighting unit made in accordance with principles of the disclosed subject matter, and FIGS. 2-3 are a cross-section view taken along line A-A as shown in FIG. 1 and a cross-section view taken along line B-B shown in FIG. 1, respectively. An LED lighting unit 1 can include a plurality of LED chips 2 and a casing 3 that includes the LED chips 2 mounted therein. The casing 3 can be composed of a laminate board, and the laminate board can be composed of an insulating material such as an epoxy resin, a polyimide, a ceramic, etc.

The casing 3 can include: a first insulating board 6 having a first surface and a second surface; a second insulating board 5 having a first surface and a second surface and through-bores 15, the second surface thereof located adjacent and possibly in direct contact with the first surface of the first insulating board 6; and a third insulating board 4 having a first surface and a second surface and through-bores 14, the second surface thereof located adjacent and possibly in direct contact with the first surface of the second insulating board 5.

The first insulating board 6 can include a plurality of first conductive patterns 8 separately located on the first surface thereof, and also can include a plurality of second conductive patterns 9 independently located on the second surface thereof. Similarly, the second insulating board 5 can include a plurality of first conductive patterns 7 separately located on the first surface thereof.

In this case, the first conductive patterns 7 of the second insulating board 5 can be electrically connected to the first conductive patterns 8 of the first insulating board 6 through via holes 10 that pass through the second insulating board 5. Likewise, the first conductive patterns 8 of the first insulating board 6 can be electrically connected to the second conductive patterns 9 of the first insulating board 6 through via holes 11, which pass through the first insulating board 6.

The casing 3 can include a plurality of first cavities 12 and a plurality of second cavities 13, which have different depths by connecting the through-bores 15 of the second insulating board 5 to the through-bores 14 of the third insulating board 4. In the exemplary embodiment shown in FIG. 1, the first cavities 12 and the second cavities 13 can be alternately located at an interval in a matrix.

The first cavities 12 in which the depths are thinner (or less) in the light emitting direction than those of the second cavities 13 can be formed with the through-bores 14, which pass through the third insulating board 4 as shown in FIG. 3. Please note that the light emitting direction is a direction perpendicular and out of the drawing sheet for FIG. 1 and is upward and coincidental or parallel with axis X as shown in FIG. 2. The depth d1 of the first cavities 12 can be equal to a thickness of the third insulating board 4. A pair of the first conductive patterns 7 on the first surface of the second insulating board 5 can be exposed on a bottom surface of the first cavities 12. One of the first conductive patterns 7 can be used as a die bonding pad 16, and the other one can be used as a wire bonding pad 17.

The second cavities 13 in which the depth is thicker (or larger) in the light emitting direction than the respective depth of the first cavities 12 can be formed with the through-bore 14 and the through-bore 15, which pass through the third insulating board 4 and the second insulating board 5 as shown in FIG. 2. The through-bores 14 and the through-bores 15 can be concentrically located so as to share a center axis X, and therefore the depth D of the second cavities 13 can be equal to a sum of the thickness d1 of the third insulating board 4 and a thickness d2 of the second insulating board 5.

A pair of the first conductive patterns 8 on the first surface of the first insulating board 6 can be exposed on a bottom surface of the second cavities 13. One of the first conductive patterns 8 can be used as a die bonding pad 16, and an other one of the first conductive patterns 8 can be used as a wire bonding pad 17 in the second cavities 13.

The first and second cavities 12 and 13 shown in FIG. 1 are conical in view of the first surface of the third insulating board 4, and can be symmetrical about an axis that is parallel with the light emitting direction. However, the shape of the cavities 12 and 13 is not limited to the conical shape. The first cavities 12 can be similar to the second cavities 13 in the shape and size. In addition, the inner surfaces of these cavities 12, 13 can be continuous and smooth surfaces without a bump or noticeable difference at the joint between first and second surfaces. In this case, light emitted from the LED chips 2 may not be disturbed on the inner surfaces of these cavities 12, 13, but can be emitted toward the outside of the LED lighting unit 1 from the first and the second cavities 12 and 13 with a favorable light distribution.

The LED chips 2 having a substantially same spectrum can be mounted on the die bonding pads 16 via a conductive adhesive material, and bottom electrodes of the LED chips 2 can be electrically connected to the die bonding pads 16 corresponding to the respective LED chips 2. Upper electrodes of the LED chips 2 can be electrically connected to the wire bonding pads 17 corresponding to the respective LED chips 2 via bonding wires 18.

Peak wavelengths of the LED chips 2 can include a wavelength towards the shorter wavelength range of the visible light range, or a wavelength in an ultraviolet light range, in order to be able to excite various phosphors with light emitted from the LED chips 2. Specifically, blue LEDs having a relatively short wavelength in the visible light range, ultraviolet LEDs having a wavelength in an ultraviolet light range and the like can be used as the LED chips 2. The exemplary embodiments of the disclosed subject matter will be described using blue LEDs as the LED chips 2.

An encapsulating resin 19 that is made by dispersing a phosphor in a transparent resin can be disposed into the first cavities 12 and the second cavities 13, and the LED chips 2 including the bonding wires 18 can be encapsulated in the first and the second cavities 12 and 13 with the encapsulating resin 19. A same mixture resin can be used as the encapsulating resin 19 that is located in the first and the second cavities 12 and 13, and the mixture resin for the encapsulating resin 19 can be composed of a same transparent resin and a same phosphor that become a substantially same density in the transparent resin.

More specifically, an epoxy resin, a silicone resin and the like can be used as the transparent resin. A yellow phosphor that can emit yellow light that is a complimentary color of blue light by exciting the phosphor with the blue light emitted from the blue LED can be used, for example, as the phosphor dispersed in the transparent resin. When ultraviolet LEDs are used as the LED chips 2, other phosphors can be used as the phosphor that is dispersed in the transparent resin.

An encapsulating process that disperses the encapsulating resin 19 into the first and the second cavities 12 and 13 can be carried out by a potting method, etc. The encapsulating resin 19 can be dispersed into each of the first and the second cavities 12 and 13 by a liquid volumetric feeder such as a dispenser and the like, and therefore a predetermined volume of the encapsulating resin 19 can be dispersed into the first and the second cavities 12 and 13.

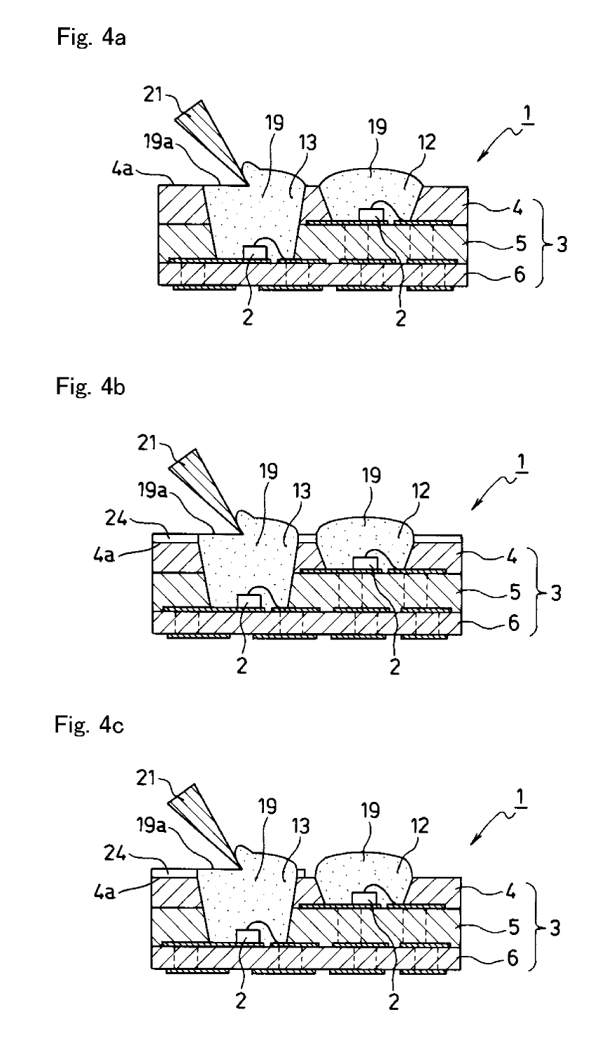

FIG. 4a is a side cross-section view showing a process in an exemplary manufacturing method for the LED lighting unit 1. When the encapsulating resin 19 is solidified after heating, because the volume of the encapsulating resin 19 may be constricted, the encapsulating resin 19 can be dispersed higher than the first surface 4a of the third insulating board 4. A surface 19a of the encapsulating resin 19 can be formed at the same level as the first surface 4a of the third insulating board 4 by cutting off the raised portion with a scraper 21 after solidifying or at the point of partially solidifying. Therefore, the above cutting process can result in an accurate quantification of the encapsulating resin 19 in the first and the second cavities 12 and 13. The resulting top surface of the LED lighting unit 1 can include the first surface 4a and top surface 19a of the encapsulating resin each located in a flat, co-planar relationship with each other.

FIGS. 4b and 4c are side cross-section views showing variations in the cutting process. In the cutting process, a mask plate 24 having a first surface and a substantially uniform thickness that includes holes corresponding to at least one of the first cavities 12 and the second cavities 13 can be placed on the first surface 4a of the third insulating board 4. The raised portion of the encapsulating resin 19 can be cut off so as to become the substantially same level as the first surface of the mask plate 24. In this case, the surface 19a of the encapsulating resin 19 can be adjusted individually on the first cavities 12 and the second cavities 13 so as not to scratch the first surface of the third insulating board 4, which may provide an outside commercial appearance for the unit.

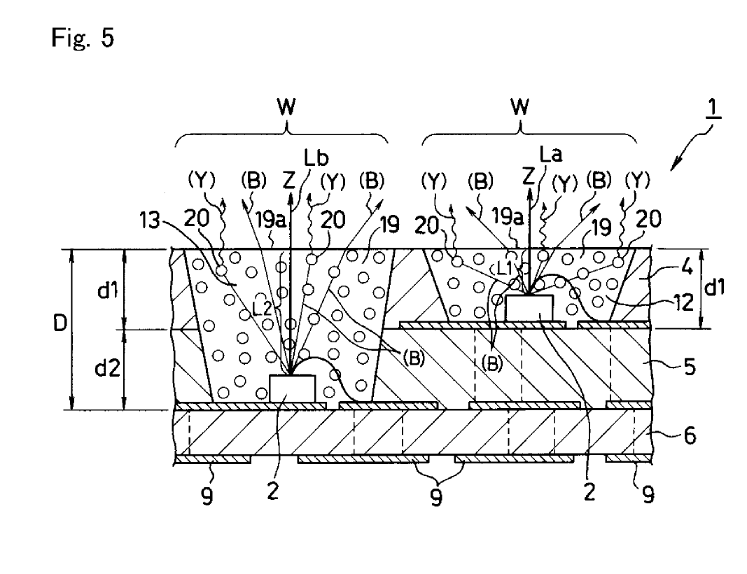

FIG. 5 is a side cross-section view for explaining an optical structure in the exemplary embodiment of the LED lighting unit 1. When providing the blue LED chips 2 with a power supply via the second conductive patterns 9 on the second surface of the first insulating board 6, the blue LED chips can emit blue light (B) with a peak wavelength of 450 nm. The phosphor 20 of the encapsulating resin 19 can be a yellow phosphor such as YAG: Ce, (Ca, Sr, Ba)₂SiO₄: Eu and the like for converting blue light to a complementary yellow light. A part of the blue light (B) emitted from the blue LED chips 2 excites the yellow phosphor and converts it to yellow light, which can be mixed with other parts of the blue light (B) emitted from the blue LED chips 2 by means of additive color mixture. Thus, the LED lighting unit 1 can emit light (W) having an approximately white color tone.

In this case, each of the path lengths along which blue light (B) emitted in a same direction from the blue LED chips 2 in the first and the second cavities 12 and 13 get to the surface 19a of the encapsulating resin 19 may be different from each other. For example, when path lengths of the light emitted in a same Z-axis direction from the blue LEDs 2 in the first and the second cavities 12 and 13 are compared, if the path length that a blue light La emitted in the Z-axis direction from the blue LEDs 2 in the first cavities 12 gets to the surface 19a is defined as L1, and if the path length that a blue light Lb emitted in the Z-axis direction from the blue LEDs 2 in the second cavities 13 gets to the surface 19a is defined as L2, the path length of Lb can become (L2−L1) longer than that of La.

Therefore, a ratio between the yellow component and the blue component in the white light emitted from the first cavities 12 may be different from the same ratio in the white light emitted from the second cavities 13. The white light emitted from the first cavities 12 may include a blue component that is greater than a blue component of the white light emitted from the second cavities 13, and the white light emitted from the second cavities 13 may include a yellow component greater than a yellow component of the white light from the first cavities 12.

That is to say, white light including a high color temperature of the blue component of light can be emitted from the first cavities 12, and the second cavities 13 can emit white light including a low color temperature of the yellow component of light. Thus, the first cavities 12 and the second cavities 13 can emit white light having different color temperatures in accordance with the depths thereof even when the same blue LEDs having the same spectrums are mounted in the first and the second cavities 12 and 13 and are encapsulated with the same encapsulating resin 19 having the same compositions.

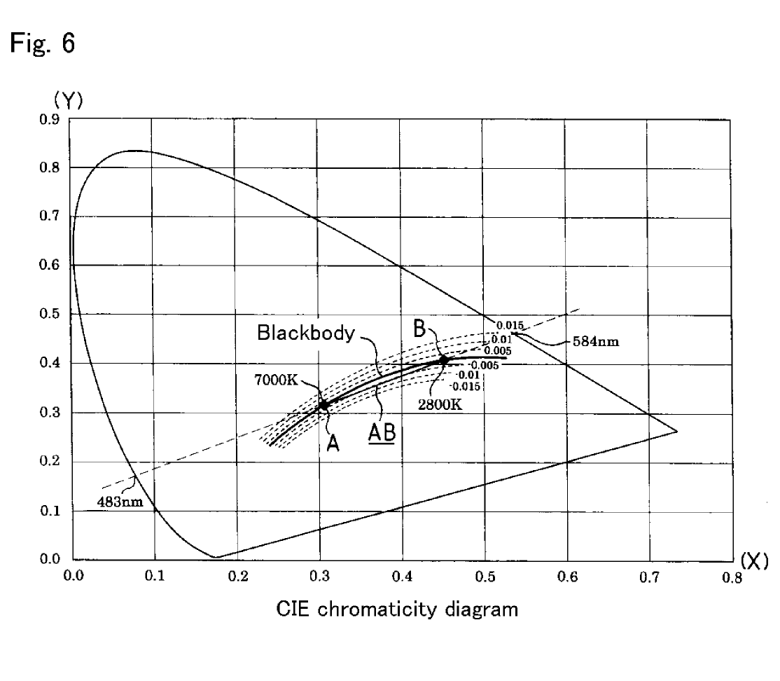

In other words, the first and the second cavities 12 and 13 can selectively emit light having a favorable color temperature according to the thickness of the encapsulating resin 19 as measure in the light emitting direction or as measured in consideration of the length of a light path that passes through the resin 19 from the LED chip(s). FIG. 6 is a chromaticity diagram showing chromaticity on a chromaticity coordinate for an exemplary embodiment of the LED lighting unit 1 made in accordance with principles of the disclosed subject matter.

The depth d1 of the first cavities 12 is determined so that white light having a cool color emitted from the first cavities 12 can be located at a high color temperature A (e.g. 7,000K) on the substantially black body in the CIE chromaticity diagram. The depth D (d1+d2) of the second cavities 13 is determined so that white light having a warm color including yellow light emitted from the second cavities 13 can be located at a low color temperature B (e.g. 2,800K) on the substantially black body in the CIE chromaticity diagram.

In this case, the LED lighting unit 1 can emit mixture light having a color temperature that is located on an approximate line AB of the substantially black body between the points A and B using the light emitted from the first and the second cavities 12 and 13 and by changing the driving currents of the LED chips 2. In addition, the mixture light can be close to natural light because the color temperature can be located on the substantially black body. The driving currents of the LED chips 2 can be easily changed by controlling the current or the duty ratio of the A/C pulse driving.

The thicknesses of the encapsulating resin 19 that can change the color temperatures of the light emitted from the first and the second cavities 12 and 13 can be determined by the depth d1 of the third insulating board 4 and the depth d2 of the second insulating board 5. Therefore, the second insulating board 5 having a favorable depth and the through-bores 15 located at favorable positions is prepared, and the third insulating board 4 having a favorable depth and the through-bores 14 located at favorable positions is prepared. The first cavities 12 and the second cavities 13 can be formed with a simple structure and high accuracy by integrating the second and the third insulating board 5 and 4, while maintaining the depths d1 and d2 with high accuracy.

Thus, the LED lighting unit 1 of the disclosed subject matter can emit mixture light having a favorable color temperature using the light emitted from the first and the second cavities 12 and 13 while maintaining high color reproducibility in the optical light-emitting characteristics thereof. Evaluation results between the depth of the encapsulating resin 19 and the color temperature of the mixture light will now be given.

Blue LEDs having a peak wavelength of around 450 nm composed of GaN were mounted in each of cavities having depths of 0.5, 0.55, 0.65, 0.75, 0.85 and 0.95 millimeters. The encapsulating resin was made by mixing a yellow phosphor having a peak wavelength of around 570 nm composed of a silicate structure: Eu with a silicone resin at a ratio by weight of approximately 11 percents. The encapsulating resin was disposed into the respective cavities in which the blue LEDs were mounted, and were solidified by heating. Then, the top surface of the encapsulating resin was formed at the same level as the top surface of the cavities by cutting off raised portions of the encapsulating resin with a scraper.

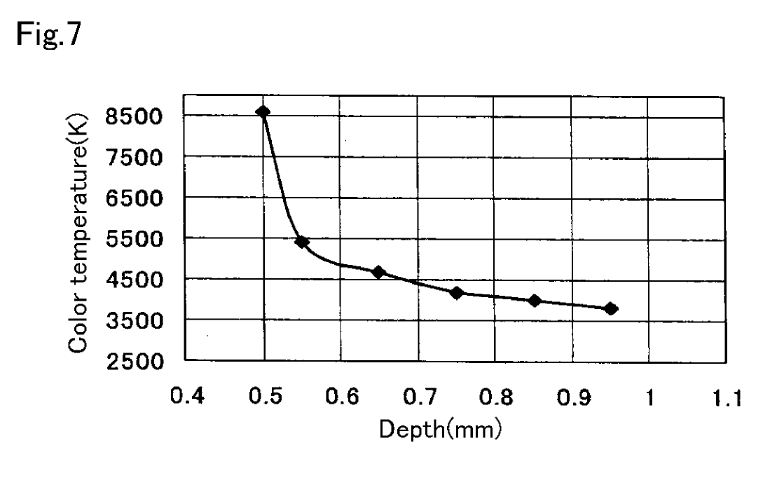

FIG. 7 is a graph showing the relation between the color temperature and the depth of the cavity that is equal to the thickness of the encapsulating resin 19 according to the evaluation results. When the depth of the cavity changes from 0.5 to 0.95 millimeters, the color temperature of the mixture light changes from approximately 8,500 K to 3,800 K. The changing ratio of the color temperature in the light having a high color temperature of cool color may be larger than that in the light having a low color temperature of warm color with respect to the depth of the cavity.

In particular, when the depth of the cavity becomes deeper than 0.6 millimeters, the changing ratio of the color temperature in the light having a low color temperature of warm color becomes gradual. This is due to a sharp decline of the blue component in the mixture light as the depth of the cavity becomes deeper, although the blue component may be large at a low depth of the cavity. When the depth of the cavity becomes deeper than around 0.5 millimeters, the density of the phosphor in the encapsulating resin 19 can become high, and therefore the blue component in the mixture light can rapidly decrease while the yellow component in the mixture light increases.

According to the evaluation results, the depths of the first and the second cavities 12 and 13 manufactured with high accuracy can provide control the color temperature of the mixture light within a favorable range in the large range of the changing ratio of the color temperature. In the LED lighting unit of the disclosed subject matter, the depths of the first and the second cavities 12 and 13 can be determined by the thicknesses of the second and the third insulating board 5 and 4.

Therefore, the depths of the first and the second cavities 12 and 13 can be determined with high accuracy by using an insulating board with high dimensional accuracy in thickness. In this case, the color temperature of the mixture light can be easily controlled with high accuracy even in the range of a large changing ratio with respect to the color temperature, and this is because it is easy to use the insulating board manufactured with high dimensional accuracy in thickness.

According to an LED light unit 1 of the disclosed subject matter as described above, the casing 3 can include the first cavities 12 and the second cavities 13 having depths that are different from those of the first cavities 12. The different depths of the second cavities 13 can be formed by connecting the second through-bore 14 of the third insulating board 4 to the through-bore of the second insulating board 5 with high accuracy while the casing 3 is made by laminating the insulating boards 4-5 with a simple structure. In addition, the first and the second cavities 12 and 13 can include one kind of LED chip mounted therein and can include one kind of encapsulating resin located therein.

Therefore, the optical characteristics of the light emitted from the first cavities 12 and the second cavities 13 can be controlled with high accuracy by changing the thicknesses of the encapsulating resin 19 based upon the depths of these cavities. The variability of the optical characteristics can be reduced as compared to a conventional LED lighting unit, which includes a plurality of kinds of LED chip and/or encapsulating resin, etc. Thus, an LED lighting unit of the disclosed subject matter can emit light having a favorable color temperature that is close to a natural light, and can maintain the high color reproducibility.

A method for manufacturing an LED lighting unit will now be given. The manufacturing method can include: providing the casing 3 that includes a first surface and the first cavity having a bottom surface being substantially parallel to the first surface and the second cavity having a bottom surface being substantially parallel to the first surface; mounting the plurality of LED chips 2 on the bottom surfaces in the first cavity and the second cavity; encapsulating the LED chips 2 in the first cavity and the second cavity with the encapsulating resin 19; solidifying the encapsulating resin 19; and cutting off the encapsulating resin 19 so that the top surface of the encapsulating resin 19 becomes the substantially same level as the first surface of the casing 3 in the solidifying process or after the solidifying process.

In the above-described method, the manufacturing method can further include: placing a mask plate 24 having a first surface that includes holes corresponding to at least one of the first cavity and the second cavity and which are formed in a substantially uniform thickness on the first surface of the casing 3 so as to be located opposite the first surface before the encapsulating process; cutting off the encapsulating resin 19 so that the top surface is located at substantially the same level as the first surface of the mask plate 24 in the cutting process; and replacing the mask plate.

According to a method for manufacturing an LED lighting unit, the thicknesses of the encapsulating resins 19 based upon the depths of the cavities can be formed with high accuracy using a simple manufacturing machine. In addition, the thicknesses of the encapsulating resins 19 can also be adjusted individually using the mask plate 24. Thus, the manufacturing method can provide an LED lighting unit having the above-described qualities.

While there has been described what are at present considered to be exemplary embodiments of the invention, it will be understood that various modifications may be made thereto, and it is intended that the appended claims cover such modifications as fall within the true spirit and scope of the invention. All conventional art references described above are herein incorporated in their entirety by reference.

What is claimed is:

1. An LED lighting unit, comprising:
a casing having a first surface, at least one first cavity, and at least one second cavity, the casing including a laminate board, the laminate board including a plurality of insulating boards, the at least one first cavity defined by an opening adjacent the first surface, an inner surface, and a bottom surface that includes an exposed portion of one of the insulating boards of the laminate board, the at least one second cavity defined by an opening adjacent the first surface, an inner surface, and a bottom surface that includes an exposed portion of one of the insulating boards of the laminate board, and the at least one second cavity located adjacent the at least one first cavity;
a plurality of die bonding pads each including a portion of a conductive pattern, and each located on the bottom surface of a respective one of the at least one first cavity and the at least one second cavity;
a plurality of wire bonding pads each including a portion of a conductive pattern, and each located on the bottom surface of a respective one of the at least one first cavity and the at least one second cavity while being located adjacent a respective one of the die bonding pads;
a plurality of LED chips having electrodes and a peak wavelength, and each of the plurality of LED chips mounted on a respective one of the die bonding pads, and each of the electrodes being electrically connected to a respective one of the die bonding pads and a respective one of the wire bonding pads; and
an encapsulating resin having a first top surface and a second top surface, the encapsulating resin including a transparent resin and a phosphor, the encapsulating resin being disposed at least in the at least one first cavity and the at least one second cavity so as to encapsulate the LED chips, the first top surface of the encapsulating resin being substantially parallel with the bottom surface of the at least one first cavity, the second top surface of the encapsulating resin being substantially parallel with the bottom surface of the at least one second cavity, and wherein a shortest distance between the first top surface of the encapsulating resin and the bottom surface of the at least one first cavity is shorter than a shortest distance between the second top surface of the encapsulating resin and the bottom surface of the at least one second cavity.

2. The LED lighting unit according to claim 1, wherein the inner surface of the at least one first cavity and the inner surface of the at least one second cavity forms a continuous and smooth surface, and the opening of the at least one first cavity and the opening of the at least one second cavity are formed in a substantially same shape.

3. The LED lighting unit according to claim 1, wherein the first top surface and the second top surface of the encapsulating resin are substantially coplanar with the first surface of the casing.

4. The LED lighting unit according to claim 2, wherein the first top surface and the second top surface of the encapsulating resin are substantially coplanar with the first surface of the casing.

5. The LED lighting unit according to claim 1, wherein the peak wavelength of the LED chips is within a range of wavelength for blue light or ultraviolet light, and each chromaticity of light emitted from the at least one first cavity and the at least one second cavity is located on a substantially black body or at a white area that is close to the black body in a CIE chromaticity diagram.

6. The LED lighting unit according to claim 2, wherein the peak wavelength of the LED chips is within a range of wavelength for blue light or ultraviolet light, and each chromaticity of light emitted from the at least one first cavity and the at least one second cavity is located on a substantially black body or at a white area that is close to the black body in a CIE chromaticity diagram.

7. The LED lighting unit according to claim 3, wherein the peak wavelength of the LED chips is within a range of wavelength for blue light or ultraviolet light, and each chromaticity of light emitted from the at least one first cavity and the at least one second cavity is located on a substantially black body or at a white area that is close to the black body in a CIE chromaticity diagram

8. The LED lighting unit according to claim 4, wherein the peak wavelength of the LED chips is within a range of wavelength for blue light or ultraviolet light, and each chromaticity of light emitted from the at least one first cavity and the at least one second cavity is located on a substantially black body or at a white area that is close to the black body in a CIE chromaticity diagram.

9. An LED lighting unit, comprising:
a power supply having at least two current supplies;
a first insulating board including a first surface and a second surface, the first surface including at least one die bonding pad and at least one wire bonding pad each including a portion of a conductive pattern, the second surface including a first electrode and a second electrode, the first electrode electrically connected to one current supply of the power supply, the second electrode electrically connected to the at least one die bonding pad and the at least one wire bonding pad through at least one via-bore and the conductive pattern of the first surface, and the second electrode electrically connected to an other current supply of the power supply;
a second insulating board including a first surface and a second surface and at least one through-bore having an inner surface, the first surface of the second insulating board including at least one die bonding pad and at least one wire bonding pad that include a portion of a conductive pattern, the second surface of the second insulating board being laminated with the first surface of the first insulating board so that the at least one bonding pad and the at least one wire bonding pad of the first insulating board are exposed in the at least one through-bore, and each of the at least one die bonding pad and the at least one wire bonding pad is electrically connected to the first electrode on the second surface of the first insulating board through via-bores and the conductive pattern of both the second insulating board and the first insulating board;
a third insulating board including a first surface, a second surface, at least one first through-bore having an inner surface and at least one second through-bore having an inner surface, the second surface of the third insulating board being laminated with the first surface of the second insulating board so that the at least one bonding pad and the at least one wire bonding pad of the second insulating board are exposed in the at least one first through-bore and so that the at least one second through-bore is connected to the at least one through-bore of the second insulating board;
a plurality of LED chips having electrodes and a peak wavelength, and each of the LED chips being mounted on a respective one of the die bonding pads, and each of the electrodes being electrically connected to a respective one of the at least one die bonding pads and a respective one of each of the at least one wire bonding pad of the first insulating board and the second insulating board; and
an encapsulating resin having a first top surface and a second top surface and including a transparent resin and a phosphor, the encapsulating resin being disposed at least in the at least one first through-bore of the third insulating board and both the at least one second through-bore of the third insulating board and the at least one through-bore of the second insulating board so as to encapsulate the LED chips, the first top surface of the encapsulating resin being substantially parallel with the first surface of the second insulating board, the second top surface of the encapsulating resin being substantially parallel with the first surface of the first insulating board, and wherein a shortest distance between the first top surface of the encapsulating resin and the first surface of the second insulating board is shorter than a shortest distance between the second top surface of the encapsulating resin and the first surface of the first insulating board.

10. The LED lighting unit according to claim 9, wherein the inner surface of the at least one first through-bore of the third insulating board and both the at least one second through-bore of the third insulating board and the at least one through-bore of the second insulating board form a continuous and smooth surface, and the at least one first through-bore and the at least one second through-bore of the third insulating board are formed in a substantially same shape.

11. The LED lighting unit according to claim 9, wherein the first top surface and the second top surface of the encapsulating resin are substantially coplanar with the first surface of the third insulating board.

12. The LED lighting unit according to claim 10, wherein the first top surface and the second top surface of the encapsulating resin are substantially coplanar with the first surface of the third insulating board.

13. The LED lighting unit according to claim 9, wherein the peak wavelength of the LED chips is within a range of wavelength for blue light or ultraviolet light, and each chromaticity of light emitted from the at least one first through-bore and the at least one second through-bore of the third insulating board is located on a substantially black body or at a white area that is close to the black body in a CIE chromaticity diagram.

14. The LED lighting unit according to claim 10, wherein the peak wavelength of the LED chips is within a range of wavelength for blue light or ultraviolet light, and each chromaticity of light emitted from the at least one first through-bore and the at least one second through-bore of the third insulating board is located on a substantially black body or at a white area that is close to the black body in a CIE chromaticity diagram.

15. The LED lighting unit according to claim 11, wherein the peak wavelength of the LED chips is within a range of wavelength for blue light or ultraviolet light, and each chromaticity of light emitted from the at least one first through-bore and the at least one second through-bore of the third insulating board is located on a substantially black body or at a white area that is close to the black body in a CIE chromaticity diagram.

16. The LED lighting unit according to claim 12, wherein the peak wavelength of the LED chips is within a range of wavelength for blue light or ultraviolet light, and each chromaticity of light emitted from the at least one first through-bore and the at least one second through-bore of the third insulating board is located on a substantially black body or at a white area that is close to the black body in a CIE chromaticity diagram.

17. A method for manufacturing an LED lighting unit comprising:
providing a casing that includes a first surface, at least one first cavity having conductive patterns on a bottom surface that is substantially parallel to the first surface, and at least one second cavity having conductive patterns on a bottom surface of the second cavity that is substantially parallel to the first surface;
mounting an LED chip having electrodes on the bottom surface of the at least one first cavity and the bottom surface of the at least one second cavity, each of the electrodes electrically connected to a respective one of the conductive patterns in the at least one first cavity and the at least one second cavity;
encapsulating the LED chips in the at least one first cavity and the at least one second cavity with an encapsulating resin composed of a transparent resin and a phosphor;
solidifying the encapsulating resin; and
cutting off the encapsulating resin to form a top surface that is substantially coplanar with the first surface of the casing during the solidifying or after the solidifying of the encapsulating resin.

18. The method for manufacturing an LED lighting unit according to 17, further comprising:
placing a mask plate having a first surface that includes holes corresponding to at least one of the first cavity and the second cavity, and is formed in a substantially uniform thickness, on the first surface of the casing so as to be located opposite the first surface of the casing before encapsulating the LED chips;
cutting off the encapsulating resin such that a top surface of the encapsulating resin is substantially coplanar with the first surface of the mask plate; and
replacing the mask plate.

19. The method for manufacturing an LED lighting unit according to claim 17, wherein a distance between the first surface of the casing and the bottom surface of the at least one first cavity is shorter than a distance between the first surface of the casing and the bottom surface of the at least one second cavity.

20. The method for manufacturing an LED lighting unit according to claim 18, wherein a distance between the first surface of the mask plate and the bottom surface of the at least one first cavity is shorter than a distance between the first surface of the mask plate and the bottom surface of the at least one second cavity.

21. The LED lighting unit according to claim 1, wherein each of the insulating boards has a substantially uniform thickness.

22. The LED lighting unit according to claim 9, wherein each of the first, second, and third insulating boards has a substantially uniform thickness.
